(19) United States
(12) Patent Application Publication
(10) Pub. No.: US 2025/0311128 A1
(43) Pub. Date: Oct. 2, 2025

(54) DISPLAY APPARATUS

(71) Applicant: Samsung Display Co., LTD., Yongin-si (KR)

(72) Inventors: Yoonseop SHIM, Yongin-si (KR); Woongsoo JEON, Yongin-si (KR)

(21) Appl. No.: 19/008,970

(22) Filed: Jan. 3, 2025

(30) Foreign Application Priority Data
Mar. 28, 2024 (KR) 10-2024-0042717

(51) Int. Cl. H05K 5/03; H10K 59/80

(52) U.S. Cl. CPC H05K 5/03; H10K 59/872

(57) ABSTRACT

A display apparatus includes a display panel provided with an accommodation groove defined in an outer portion thereof, a cover member disposed on the display panel, and a reinforcement layer accommodated in at least a portion of the accommodation groove and attached to the cover member.

This application claims priority to Korean Patent Application No. 10-2024-0042717, filed on Mar. 28, 2024, and all the benefits accruing therefrom under 35 U.S.C. § 119, the content of which in its entirety is herein incorporated by reference.

### BACKGROUND

### 1. Field

One or more embodiments relate to an apparatus, and more particularly, to a display apparatus.

### 2. Description of the Related Art

Mobile electronic devices are widely used in various fields. As mobile electronic devices, tablet personal computers (PCs) have been widely used in recent years in addition to small electronic devices such as mobile phones.

Such mobile electronic devices typically include display apparatuses to support various functions, for example, to provide visual information, such as images or videos, to users. Recently, as other parts for driving display apparatuses have been miniaturized, the proportion occupied by display apparatuses in electronic devices has gradually been increasing. Structures capable of being bent from a flat state to have a certain angle are also under development.

### SUMMARY

There are cases where a force is applied to display apparatuses. In such cases, the display apparatuses may be broken or damaged and may not effectively perform their own functions. One or more embodiments provide a display apparatus that effectively withstand an external impact or force applied thereto, such that a separation between a display panel and a cover member of the display apparatus is effectively prevented.

According to one or more embodiments, a display apparatus includes a display panel provided with an accommodation groove defined in an outer portion thereof, a cover member disposed on the display panel, and a reinforcement layer accommodated in at least a portion of the accommodation groove and attached to the cover member.

In an embodiment, a planar shape of the accommodation groove may be polygonal or a U-like shaped.

In an embodiment, a planar shape of the display panel may be rectangular, and the accommodation groove may be defined on a short side of the planar shape of the display panel.

In an embodiment, the reinforcement layer may include a first reinforcement layer disposed inside the accommodation groove, and a second reinforcement layer disposed outside of the accommodation groove.

In an embodiment, a sum of a width of the first reinforcement layer and a width of the second reinforcement layer may be about 1 millimeter (mm) or less.

In an embodiment, the display apparatus may further include a support on which the cover member is seated.

In an embodiment, an inner side surface of the support and the reinforcement layer may be apart from each other.

In an embodiment, the display panel may include an organic light-emitting element.

In an embodiment, a width of a planar shape of the accommodation groove may be gradually reduced from one point to an end of a planar shape of the accommodation groove.

In an embodiment, the accommodation groove may be provided in plurality, and one of a plurality of accommodation grooves and another of the plurality of accommodation grooves may be arranged to be symmetrical to each other with respect to an imaginary straight line perpendicular to one side of the display panel.

According to one or more embodiments, a display apparatus includes a display panel, a cover member disposed on the display panel, a reinforcement layer inserted into the display panel, and a support disposed apart from the reinforcement layer and supporting the cover member.

In an embodiment, a planar shape of the reinforcement layer may be polygonal, partially circular, or partially elliptical.

In an embodiment, the reinforcement layer may be in contact with the cover member.

In an embodiment, a portion of the reinforcement layer may be inserted into the display panel, and another portion of the reinforcement layer may protrude outward from the display panel in a plan view.

In an embodiment, the display panel may have a rectangular shape, and the reinforcement layer may be arranged on a short side of the display panel.

In an embodiment, the reinforcement layer may be provided in plurality, and one of a plurality of reinforcement layers and another reinforcement layer may be arranged to be symmetrical to each other with respect to one side of the display panel.

In an embodiment, the reinforcement layer may be in contact with an edge of the display panel on at least two sides.

In an embodiment, a width of the reinforcement layer may be gradually reduced from one point to an end of the reinforcement layer.

In an embodiment, an edge of the reinforcement layer and an edge of the display panel may form a straight line.

In an embodiment, the display apparatus may further include a bracket on which the support is seated.

Other features advantages of embodiments of the disclosure will become better understood through the accompanying drawings, the appended claims, and the detailed description.

### BRIEF DESCRIPTION OF THE DRAWINGS

The above and other features of certain embodiments of the disclosure will be more apparent from the following description taken in conjunction with the accompanying drawings, in which:

FIG. 1 is a perspective view of a display apparatus according to an embodiment;

FIG. 2 is a cross-sectional view illustrating a portion of the display apparatus illustrated in FIG. 1;

FIG. 3 is a rear view of a cover member and a display panel illustrated in FIG. 2;

FIG. 4 is an enlarged rear view of a region A of FIG. 3;

FIG. 5 is a plan view of the display panel illustrated in FIG. 2;

FIGS. 6A and 6B are cross-sectional views schematically illustrating embodiments of the display panel of FIG. 5 taken along line VI-VI′ of FIG. 5;

FIG. 7 is a cross-sectional view schematically illustrating a portion of the display panel of FIG. 5 taken along line VII-VII′ of FIG. 5;

FIGS. 8A and 8B are schematic circuit diagrams of embodiments of a pixel of the display panel illustrated in FIG. 5;

FIG. 9 is a rear view illustrating a portion of a display apparatus according to another embodiment;

FIG. 10A is a rear view illustrating a portion of a display apparatus according to another embodiment;

FIG. 10B is a rear view illustrating a portion of a display apparatus according to another embodiment;

FIG. 11A is a rear view illustrating a portion of a display apparatus according to another embodiment; and

FIG. 11B is a rear view illustrating a portion of a display apparatus according to another embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

As the present description allows for various changes and numerous embodiments, certain embodiments will be illustrated in the drawings and described in detail in the written description. Effects and features of the present disclosure, and methods of achieving them will be clarified with reference to embodiments described below in detail with reference to the drawings. However, the present disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.”. As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Also, sizes of elements in the drawings may be exaggerated or reduced for convenience of explanation. For example, because sizes and thicknesses of elements in the drawings are arbitrarily illustrated for convenience of explanation, the disclosure is not limited thereto.

The X-axis, the Y-axis, and the Z-axis shown in the drawings are not limited to three axes of the rectangular coordinate system and may be interpreted in a broader sense. For example, the X-axis, the Y-axis, and the Z-axis may be perpendicular to one another or may represent different directions that are not perpendicular to one another.

When a certain embodiment is implemented differently, a specific process sequence may be performed differently from a sequence described herein. For example, two consecutively described processes may be performed substantially at the same time or performed in an order opposite to the stated order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

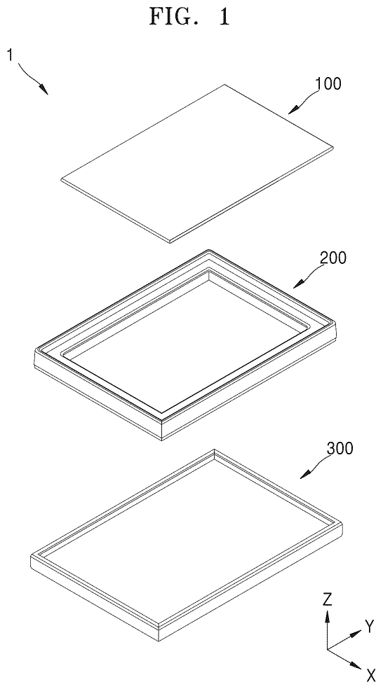

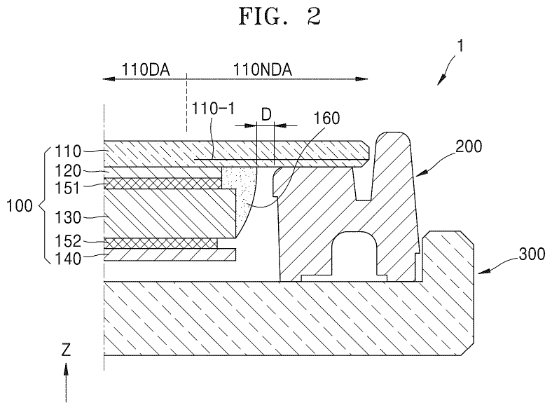

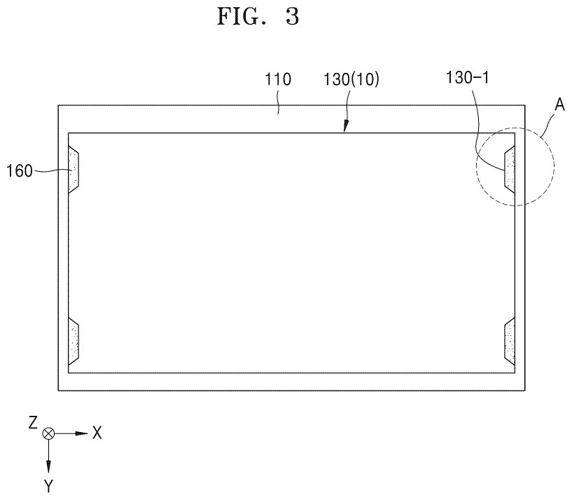

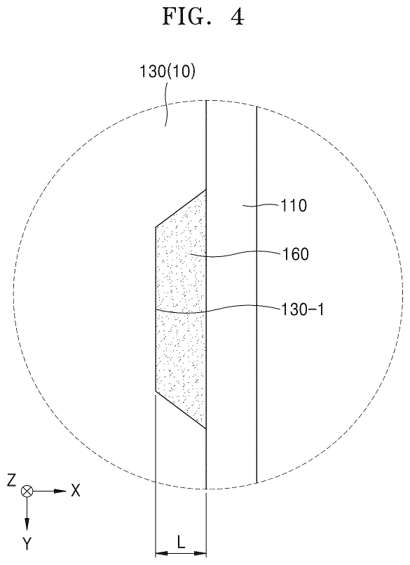

FIG. 1 is a perspective view of a display apparatus 1 according to an embodiment. FIG. 2 is a cross-sectional view illustrating a portion of the display apparatus 1 illustrated in FIG. 1. FIG. 3 is a rear view of a cover member 110 and a display panel 130 illustrated in FIG. 2. FIG. 4 is an enlarged rear view of a region A of FIG. 3.

Referring to FIGS. 1 to 4, an embodiment of the display apparatus 1 may include a display module 100, a support 200, and a bracket 300.

The display module 100 may be configured to display an image. In an embodiment, as shown in FIG. 2, the display module 100 may include the cover member 110, a functional layer 120, the display panel 130, and a back member 140.

The cover member 110 may be disposed on the display panel 130. In an embodiment, the cover member 110 may cover an upper portion of the display panel 130. Accordingly, the cover member 110 may protect a top surface of the display panel 130. Here, the top surface of the display panel 130 may be a display surface, through which the image is displayed or output.

In an embodiment, the cover member 110 may include a transmission cover (or a transmission portion) 110DA corresponding to the display panel 130 and a light blocking cover (or a light blocking portion) 110NDA corresponding to an area other than the display panel 130. The light blocking cover 110NDA may include an opaque material that blocks light. The light blocking cover 110NDA may include a pattern that may be shown to a user when an image is not displayed.

The display panel 130 may be disposed below the cover member 110. The display panel 130 may overlap the transmission cover 110DA of the cover member 110.

In an embodiment, although not illustrated, the cover member 110 may include a cover window (not shown) and a protection member (not shown). In an embodiment, the cover window may include a transparent material. In such an embodiment, the cover window may include glass, transparent synthetic resin, etc. The cover window may include at least one layer or have a layered structure.

In an embodiment, the protection member may be disposed on a top surface of the cover window and may effectively prevent or substantially minimize an occurrence of scratches on the cover window. In an embodiment, an opaque layer 110-1 may be disposed on a portion of the cover window and/or a portion of the protection member. In an embodiment, the opaque layer 110-1 may be arranged at an edge portion of the cover window or an edge portion of the protection member. The opaque layer 110-1 may block light and may be arranged in the light blocking cover 110NDA of the cover member 110.

The display panel 130 may include a display area (not shown) in which an image is displayed, and a peripheral area (not shown) around the display area. Sub-pixels each including a display element may be arranged in the display area. In an embodiment, a plurality of sub-pixels may be provided. The sub-pixels may be apart from each other when viewed in a plan view. Some sub-pixels, other sub-pixels, and still other sub-pixels may emit light of different colors, respectively. The display apparatus 1 may provide an image by using pieces of light emitted from the sub-pixels arranged in the display area, and the peripheral area may be a non-display area in which the sub-pixels are not arranged.

The display panel 130 may display (or output) information processed by the display apparatus 1. In an embodiment, for example, the display panel 130 may display execution screen information of an application driven by the display apparatus 1, or user interface (UI) or graphical user interface (GUI) information based on the execution screen information. The display panel 130 may include a display layer configured to display an image and a touch sensor layer (not shown) configured to sense user touch input. In such an embodiment, the display panel 130 may function as one of input devices configured to provide an input interface between the display apparatus 1 and the user and may also function as one of output devices configured to provide an output interface between the display apparatus 1 and the user.

Hereinafter, an embodiment where the display apparatus 1 is an organic light-emitting display apparatus will be described as an example, but the display apparatus 1 according to embodiments of the disclosure is not limited thereto. In another embodiment, the display apparatus 1 may include an inorganic light-emitting display (or an inorganic electroluminescence (EL) display), a quantum dot light-emitting display, or the like. For example, an emission layer of a display element provided in the display apparatus 1 may include an organic material, an inorganic material, or quantum dots, may include an organic material and quantum dots, or may include an inorganic material and quantum dots.

In an embodiment, the display panel 130 may be a flexible display panel that is bendable, foldable, or rollable. In such an embodiment, the display panel 130 may be a foldable display panel, a curved display panel with a curved display surface, a bended display panel in which areas other than a display surface are bent, a rollable display panel, or a stretchable display panel. In an embodiment, the display panel 130 may be a rigid display panel that is rigid and is not easily bendable.

The display panel 130 may be connected to a display circuit board (not shown) through an anisotropic conductive film.

A touch sensor driver (not shown) may be disposed on the display circuit board. In an embodiment, although not illustrated, a display driver (not shown) may be directly disposed on a substrate 10 of the display panel 130. In another embodiment, the display driver may be disposed on the display circuit board. Hereinafter, for convenience of description, embodiments where the display driver is disposed on the display circuit board will be mainly described in detail.

At least a portion of the substrate 10 of the display panel 130 may be bendable. In an embodiment, a bending protection layer may be disposed on the bent portion of the substrate 10 to effectively prevent cracks from occurring in the substrate 10. The bending protection layer may include, for example, polymer resin, such as polyethylene terephthalate (PET) or polyimide (PI).

In an embodiment, the display apparatus 1 may include a panel protection member (not shown) as the back member 140 disposed below the display panel 130. In another embodiment, the display apparatus 1 may include, as the back member 140, a digitizer (not shown) configured to receive an external signal. In another embodiment, the display apparatus 1 may include a panel protection member and a digitizer as the back member 140. In another embodiment, the back member 140 may include a panel protection member, a digitizer, and a display circuit board (not shown).

In an embodiment, the touch sensor layer may be provided in the form of a panel or a film. Alternatively, the touch sensor layer may be integrally formed with the display panel 130. In an embodiment, for example, where the touch sensor layer is in the form of a film, the touch sensor layer may be integrally formed with an encapsulation layer to encapsulate the display panel 130.

In another embodiment, the touch sensor layer may have electrodes arranged on the display panel 130 in the form of a pattern. In such an embodiment, wires may be arranged to cross each other on the encapsulation layer and the change in capacitance varying depending on the user touch may be measured at the crossing point. The touch sensor layer may be connected to the display circuit board.

The touch sensor driver may apply touch driving signals to the touch sensor layer, may sense first sensing signals sensed from the touch sensor layer, and may analyze the first sensing signals to calculate a user touch position. In addition, the touch sensor driver may apply touch driving signals to a sensor (not shown), may sense second sensing signals sensed from the sensor, and may analyze the second sensing signals to calculate a touch position of a signal inputter (not shown).

In an embodiment, the functional layer 120 may be disposed on the touch sensor layer. In such an embodiment, the functional layer 120 may be disposed on a first adhesive member 151 that is disposed on the touch sensor layer. The functional layer 120 may include an anti-reflection layer. The anti-reflection layer may reduce the reflectance of light (external light) incident from the outside through the display apparatus 1.

In some embodiments, the anti-reflection layer may be provided as a polarizing film. The polarizing film may include a linear polarizing plate and a phase retardation film such as a λ/4 plate (a quarter-wave plate). The phase retardation film may be disposed on the touch sensor layer, and the linear polarizing plate may be disposed on the phase retardation film.

In an embodiment, the anti-reflection layer may include a black matrix and a filter layer including color filters. The color filters may be arranged based on the color of light emitted from each sub-pixel of the display panel 130. In an embodiment, for example, the filter layer may include red, green, or blue color filters. In such an embodiment, the filter layer may be disposed on the touch sensor layer of the display panel 130 without using a separate adhesive layer.

In an embodiment, the anti-reflection layer may include a destructive interference structure. The destructive interference structure may include a first reflection layer and a second reflection layer on different layers from each other. First reflected light and second reflected light respectively reflected from the first reflection layer and the second reflection layer may destructively interfere with each other, and thus, the reflectance of external light may be reduced.

In an embodiment, the functional layer 120 may further include a shock absorption layer. In such an embodiment, the shock absorption layer may protect structures, such as the display panel therebelow, from external shock. In an embodiment, the shock absorption layer may be a polymer film. The polymer film may include, for example, at least one of polyethylene terephthalate (PET), polyethylene naphthalate (PEN), polyether sulfone (PES), polyimide (PI), polyarylate (PAR), polycarbonate (PC), polymethyl methacrylate (PMMA), or cycloolefin copolymer (COC).

In an embodiment, the functional layer 120 may also include an anti-reflection layer and a shock absorption layer. In such an embodiment, the anti-reflection layer and the shock absorption layer may be sequentially stacked on the display panel 130 or the touch sensor layer.

The display circuit board may be attached to one side of the display panel 130. In an embodiment, for example, the display circuit board may be attached to a pad provided on one side of the display panel 130 by using an anisotropic conductive film.

The display circuit board may be bent downward from the upper portion of the display panel 130. The display circuit board may be connected to a main circuit board (not shown) through a display connector (not shown).

In an embodiment, the support 200 may be disposed or provided between the cover member 110 and the bracket 300 and may support the cover member 110. In such an embodiment, the support 200 may have a groove in the upper portion and/or the lower section thereof in a cross-sectional view. In addition, the support 200 may include a flat surface so that the bottom surface of the cover member 110 is stably seated thereon, and a portion (e.g., an edge portion) of the support 200 may protrude to effectively prevent an end of the cover member 110 from being pushed outwardly. In addition, the support 200 may be formed to have an arch-shaped bottom surface to absorb a portion of an external force applied to the cover member 110. The support 200 may be provided with a hole where a camera device or the like to be described below is inserted or exposed.

The bracket 300 that supports the display panel 130 may be disposed below the display panel 130. The bracket 300 may include plastic, metal, or both plastic and metal.

In an embodiment, the bracket 300 may be provided with a connector hole (not shown) through which a connector passes. In addition, the bracket 300 may be provided with a camera hole (not shown) into which a camera device (not shown) is inserted. In such an embodiment, the display apparatus 1 may further include a lower cover (not shown). The lower cover may be disposed below the main circuit board. The lower cover may be fixedly coupled to the bracket 300. The lower cover may form the outer appearance of the bottom surface of the display apparatus 1. The lower cover may include plastic, metal, or both plastic and metal.

In an embodiment, the display apparatus 1 may not include the lower cover, and the main circuit board described above may be disposed on the bracket 300. In such an embodiment, the bracket 300 may not have the separate camera hole and the connector hole. In such an embodiment, the lower cover may not be provided.

The main circuit board may include a main processor (not shown), a camera device (not shown), a main connector (not shown), and a component (not shown). The main processor may be implemented as an integrated circuit. The camera device may be disposed on both the top surface and the bottom surface of the main circuit board, and each of the main processor and the main connector may be disposed on either the top surface or the bottom surface of the main circuit board. The component may include an inputter and an outputter. In such an embodiment, the inputter may include an image inputter such as the camera device configured to input an image signal, an audio inputter such as a microphone configured to input an audio signal, and an input device configured to receive information from a user. The outputter is configured to generate an output associated with a visual, auditory or tactile sense, etc., and may include at least one of an audio outputter, a haptic module, and a light emitter. The main circuit board is not limited to those described above and various components may be disposed on the main circuit board.

In an embodiment, the display panel 130 may include an accommodation groove 130-1 in a plan view or when viewed in a Z-axis direction. Here, the Z-axis direction may be a thickness direction of the display panel 130 or a direction perpendicular to a plane on which a display surface is defined. In such an embodiment, at least a portion of a reinforcement layer 160 may be arranged to be inserted into the accommodation groove 130-1. In an embodiment, for example, the planar shape of the accommodation groove 130-1 may be trapezoidal. In addition, the reinforcement layer 160 may be completely inserted into the accommodation groove 130-1. In an embodiment, as shown in FIG. 2, the side surface of the reinforcement layer 160 may be formed to be inclined. In an embodiment, for example, the side surface of the reinforcement layer 160 in contact with the cover member 110 may be arranged farthest from the edge of the display panel 130, and the side surface of the reinforcement layer 160 adjacent to the back member 140 may be arranged closest to the edge of the display panel 130 in a plan view or when viewed in the Z-axis direction. In another embodiment, the side surface of the reinforcement layer 160 may be round or curved. In such an embodiment, the side surface of the reinforcement layer 160 may be formed to protrude outward or to be recessed inward.

In an embodiment, the outer portion of the reinforcement layer 160 arranged in the accommodation groove 130-1 and the outer portion of the display panel 130 may form an almost straight line or substantially on a same imaginary straight line. That is, the reinforcement layer 160 is completely inserted into the accommodation groove 130-1 of the display panel 130. Accordingly, when viewing the reinforcement layer 160 and the display panel 130 together in a plan view or in the Z-axis direction, the planar shape of the display panel 130 on which the reinforcement layer 160 is disposed may form a rectangle, as shown in FIG. 3. In such an embodiment, the outer portion of the reinforcement layer 160 may refer to the outer portion of a region where the reinforcement layer 160 and the cover member 110 are in contact with each other.

The reinforcement layer 160 may be in complete contact with the side surface of the display panel 130. In an embodiment, for example, the portion where the reinforcement layer 160 and the display panel 130 are in contact with each other may be in direct contact with the edge of the display panel 130, which defines the accommodation groove 130-1, at three portions. Accordingly, a bonding force between the reinforcement layer 160 and the display panel 130 may be increased.

In an embodiment, a width of the accommodation groove 130-1 (e.g., a distance from the edge of the display panel 130 where the accommodation groove 130-1 is not formed to the inner surface of the accommodation groove 130-1 that is most recessed) may be about 1 millimeter (mm) or less. In a case where the width of the accommodation groove 130-1 is greater than about 1 mm, cracks or the like may occur in the display panel 130 when an external force is applied thereto.

In such an embodiment, a width L of the reinforcement layer 160 (e.g., a distance from the portion in contact with the display panel 130 to the edge of the portion where the reinforcement layer 160 is in contact with the cover member 110) may also be about 1 mm or less. Accordingly, the reinforcement layer 160 may not interfere with the support 200, and damage to the reinforcement layer 160 due to contact with the support 200 may be substantially reduced.

In an embodiment, a distance D from the outermost portion of the reinforcement layer 160 to an inner surface, e.g., a surface of the protruding portion, of the support 200 may be about 0.5 mm or less and greater than about zero (0) mm. In such an embodiment, the interference between the reinforcement layer 160 and the support 200 may be effectively prevented.

The accommodation groove 130-1 and the reinforcement layer 160 may be apart from the corner of the display panel 130 by a certain distance. That is, in a plan view or when viewed in the Z-axis direction, when a force is applied to a portion of the display panel 130 adjacent to the corner of the display panel 130, maximum stress may occur at the edge of the display panel 130. Such stress may cause separation between the display panel 130 and the cover member 110 or damage to the display panel 130. At this time, the accommodation groove 130-1 and the reinforcement layer 160 may be arranged to overlap the edge of the display panel 130 at which maximum stress occurs in the above case. Accordingly, the reinforcement layer 160 may reduce maximum stress of the display panel 130 and reduce damage to the display panel 130 or separation between the display panel 130 and the cover member 110.

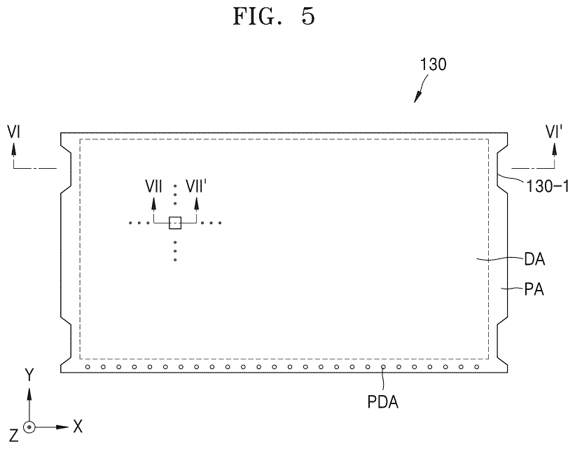

FIG. 5 is a plan view of the display panel 130 illustrated in FIG. 2.

Referring to FIG. 5, an embodiment of the display panel 130 may be a light-emitting display panel including a light-emitting element. Examples of the display panel 130 may include an organic light-emitting display panel using an organic light-emitting diode (LED) including an organic emission layer, a micro light-emitting diode display panel using a micro LED, a quantum dot light-emitting display panel using a quantum dot LED including a quantum dot emission layer, and an inorganic light-emitting display panel using an inorganic LED including an inorganic semiconductor.

The display panel 130 may be a flexible display panel that is bendable, foldable, or rollable. Examples of the display panel 130 may include a foldable display panel, a curved display panel with a curved display surface, a bended display panel in which areas other than a display surface are bent, a rollable display panel, and a stretchable display panel.

In an embodiment, the display panel 130 may be a transparent display panel that is transparently implemented so that an object or background on the bottom surface of the display panel 130 is visible from the top surface of the display panel 130. Alternatively, the display panel 130 may be a reflective display panel capable of reflecting an object or background on the top surface of the display panel 130.

The display panel 130 may include a display area DA in which an image is implemented and a peripheral area PA arranged to surround the display area DA. Separate driving circuits, pads, etc. may be arranged in this peripheral area PA.

The display panel 130 may include a pad area PDA to which the display circuit board is attached. The pad area PDA may be arranged in a portion of the peripheral area PA.

The touch sensor layer of the display panel 130 may sense user touch input by using at least one of various touch methods, including a resistive method and a capacitive method. In an embodiment, for example, where the touch sensor layer of the display panel 130 senses the user touch input by using a capacitive method, the touch sensor driver may determine the presence or absence of the user touch by applying driving signals to driving electrodes among touch electrodes and sensing voltages charged in mutual capacitances between the driving electrodes and sensing electrodes through the sensing electrodes among the touch electrodes. The user touch may include contact touch and proximity touch. The contact touch refers to a touch in which an object, such as a user's finger or a pen, is in direct contact with the cover member disposed on the touch sensor layer. The proximity touch refers to a touch in which an object, such as a user's finger or a pen, is located close to the cover member, like hovering. The touch sensor driver may be configured to transmit sensor data to the main processor according to the sensed voltages, and the main processor may be configured to analyze the sensor data to calculate touch coordinates where the touch input has occurred.

In an embodiment, a power supply configured to supply driving voltages for driving pixels, a scan driver, and the display driver of the display panel 130 may be further disposed on the display circuit board. Alternatively, the power supply may be integrated with the display driver. In such an embodiment, the display driver and the power supply may be formed as a single integrated circuit.

The display panel 130 may include at least one accommodation groove 130-1 into which the reinforcement layer (not shown) is inserted. A plurality of accommodation grooves 130-1 may be provided, that is, the accommodation groove 130-1 may be provided in plural. In such an embodiment, one of the accommodation grooves 130-1 and another of the accommodation grooves 130-1 may be arranged to be symmetrical to each other with respect to a straight line perpendicular to one side of the display panel 130. In an embodiment, for example, where the display panel 130 is rectangular, one of the accommodation grooves 130-1 and another of the accommodation grooves 130-1 may be arranged to be symmetrical to each other with respect to a straight line perpendicular to a short side and/or a long side of the display panel 130. In another embodiment, where the display panel 130 is square, one of the accommodation grooves 130-1 and another of the accommodation grooves 130-1 may be arranged to be symmetrical to each other with respect to a straight line perpendicular to one side of the display panel 130.

In an embodiment, for example, where the display panel 130 is rectangular, at least one of the accommodation grooves 130-1 may be arranged on the short side of the display panel 130. In such an embodiment, one of the accommodation grooves 130-1 and another of the accommodation grooves 130-1 may be arranged to be apart from each other in a diagonal direction of the display panel 130.

At least one of the accommodation grooves 130-1 may be arranged to be adjacent to at least one of the corners of the display panel 130. In an embodiment, for example, a distance between the center of at least one of the accommodation grooves 130-1 and the center of one side of the display panel 130 may be greater than a distance between the center of at least one of the accommodation grooves 130-1 and the corner of the display panel 130.

The structure described above may allow the display apparatus 1 to effectively withstand the force applied thereto through the reinforcement layer arranged in the accommodation groove 130-1. For example, after the display apparatus is disposed on various electronic devices, when the user applies a force to the corner of the display apparatus or the corner of the electronic device touches the ground, the display panel 130 and the cover member (not shown) may be separated from each other at the corner of the display apparatus. In an embodiment, the reinforcement layer may effectively prevent the display panel 130 and the cover member from being separated from each other. In such an embodiment, the reinforcement layer may effectively prevent the display panel 130 from being damaged by absorbing some shock applied to the corner of the display apparatus.

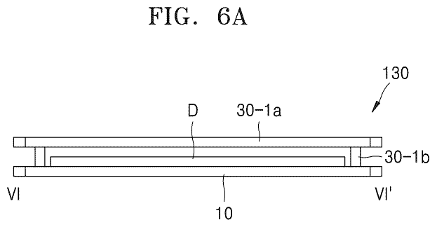

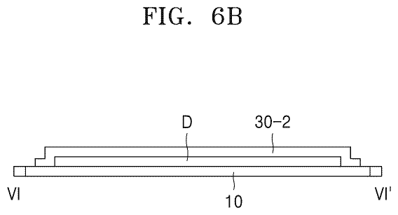

FIGS. 6A and 6B are cross-sectional views of embodiments of the display panel 130 of FIG. 5 taken along line VI-VI′ of FIG. 5.

Referring to FIGS. 6A and 6B, an embodiment of the display panel 130 may include a substrate 10, a display layer D, and an encapsulation layer. In such an embodiment, the encapsulation layer may have various shapes.

In an embodiment, the encapsulation layer may include a sealing layer 30-1b and an encapsulation substrate 30-1a, as illustrated in FIG. 6A. The sealing layer 30-1b may be arranged to surround the outer portion of the display area DA illustrated in FIG. 5. In such an embodiment, the sealing layer 30-1b may be in the form of a closed loop, and in a plan view, the display layer D may be arranged inside the sealing layer 30-1b. That is, the display layer D may be arranged to correspond to the display area DA of FIG. 5, and the sealing layer 30-1b may be arranged in the peripheral area PA illustrated in FIG. 5. The encapsulation substrate 30-1a may be arranged to face the substrate 10. In an embodiment, the accommodation groove 130-1 illustrated in FIG. 5 may be formed in the encapsulation substrate 30-1a. In another embodiment, the accommodation groove 130-1 may be formed in each of the substrate 10 and the encapsulation substrate 30-1a. In such an embodiment, the substrate 10 and the encapsulation substrate 30-1a may have shapes corresponding to each other. In such an embodiment, the accommodation groove 130-1 may be arranged outside the sealing layer 30-1b.

In another embodiment, the encapsulation layer may include a thin-film encapsulation layer 30-2, as illustrated in FIG. 6B. The thin-film encapsulation layer 30-2 may be in direct contact with an opposite electrode or an upper layer to be described below. In such an embodiment, the thin-film encapsulation layer 30-2 may cover a portion of the display area DA and the peripheral area PA to effectively prevent infiltration of external moisture and oxygen.

The thin-film encapsulation layer 30-2 may include at least one organic encapsulation layer and at least one inorganic encapsulation layer. For convenience of description, a an embodiment where the thin-film encapsulation layer 30-2 includes a first inorganic encapsulation layer (not shown), an organic encapsulation layer (not shown), and a second inorganic encapsulation layer (not shown), which are sequentially stacked on the upper layer (not shown) in this stated order, will be mainly described in detail.

In such an embodiment, the first inorganic encapsulation layer may cover the upper layer and may include silicon oxide, silicon nitride, and/or silicon oxynitride. Because the first inorganic encapsulation layer is formed along the structure therebelow, the top surface of the first inorganic encapsulation layer may not be flat. The organic encapsulation layer may cover the first inorganic encapsulation layer. Unlike the first inorganic encapsulation layer, the top surface of the organic encapsulation layer may be substantially flat. Specifically, the organic encapsulation layer may have a substantially flat top surface in a portion corresponding to the display area DA. The organic encapsulation layer may include at least one material selected from polyethylene terephthalate, polyethylene naphthalate, polycarbonate, polyimide, polyethylene sulfonate, polyoxymethylene, polyarylate, and hexamethyldisiloxane (HMDSO). The second inorganic encapsulation layer may cover the organic encapsulation layer and may include silicon oxide, silicon nitride, and/or silicon oxynitride.

In such an embodiment, the accommodation groove 130-1 may be arranged outside the thin-film encapsulation layer 30-2. That is, the accommodation groove 130-1 may be formed only in (or defined only by) the substrate 10.

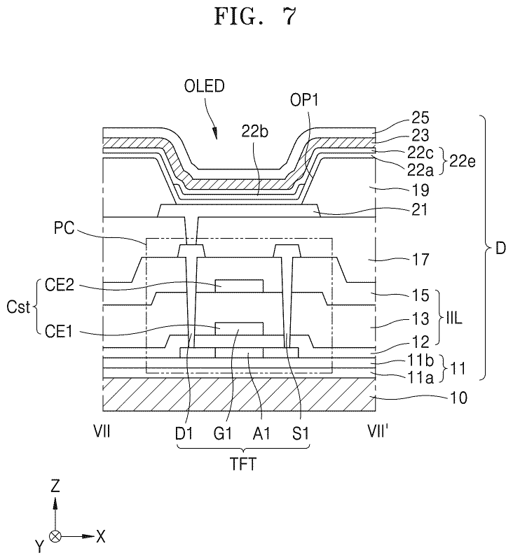

FIG. 7 is a cross-sectional view schematically illustrating a portion of the display panel of FIG. 5 taken along line VII-VII′ of FIG. 5.

Referring to FIG. 7, an embodiment of the display panel (not denoted by reference numeral) may include a substrate 10, a display layer D, an encapsulation layer (not shown), and a touch sensor layer (not shown). The display layer D may include a buffer layer 11, a circuit layer (not shown), and a display element layer (not shown), which are sequentially stacked in this stated order. In such an embodiment, the encapsulation layer may be the same as that described with reference to FIGS. 6A and 6B, and the touch sensor layer may be similar to that described with reference to FIGS. 1 to 4.

In an embodiment, as described above, the substrate 10 may include an insulating material, such as glass, quartz, or polymer resin. The substrate 10 may be a flexible substrate that is bendable, foldable, or rollable.

The buffer layer 11 may be disposed on the substrate 10. The buffer layer 11 may substantially reduce or effectively prevent infiltration of foreign material, moisture, or ambient air from below the substrate 10 and may provide a flat surface on the substrate 10. The buffer layer 11 may include an inorganic material, such as an oxide or a nitride, an organic material, or an organic/inorganic composite material and may have a single-layer or multilayer structure including an inorganic material and an organic material. A barrier layer (not shown) that effectively prevents infiltration of ambient air may be further included between the substrate 10 and the buffer layer 11. In some embodiments, the buffer layer 11 may include silicon oxide (SiO₂) or silicon nitride (SiNₓ). The buffer layer 11 may include a first buffer layer 11a and a second buffer layer 11b, which are sequentially stacked in this stated order.

The circuit layer may be disposed on the buffer layer 11 and may include a pixel circuit PC, a first gate insulating layer 12, a second gate insulating layer 13, an interlayer insulating layer 15, and a planarization layer 17. The pixel circuit PC may include a thin-film transistor TFT and a storage capacitor Cst.

The thin-film transistor TFT may be disposed on the buffer layer 11. The thin-film transistor TFT may include a first semiconductor layer A1, a first gate electrode G1, a first source electrode S1, and a first drain electrode D1. The thin-film transistor TFT may be connected to an organic light-emitting diode OLED, which is a light-emitting element, and may drive the organic light-emitting diode OLED.

In an embodiment, the first semiconductor layer A1 may be disposed on the buffer layer 11 and may include polysilicon. In another embodiment, the first semiconductor layer A1 may include amorphous silicon. In another embodiment, the first semiconductor layer A1 may include an oxide of at least one selected from indium (In), gallium (Ga), stannum (Sn), zirconium (Zr), vanadium (V), hafnium (Hf), cadmium (Cd), germanium (Ge), chromium (Cr), titanium (Ti), and zinc (Zn). The first semiconductor layer A1 may include a channel region, and a source region and a drain region doped with impurities.

The first gate insulating layer 12 may be disposed to cover the first semiconductor layer A1. The first gate insulating layer 12 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be ZnO and/or ZnO₂. The first gate insulating layer 12 may include or be defined by a single layer or layers, each layer including at least one selected from the inorganic insulating materials described above.

The first gate electrode G1 may be disposed on the first gate insulating layer 12 to overlap the first semiconductor layer A1. The first gate electrode G1 may include molybdenum (Mo), aluminum (Al), copper (Cu), titanium (Ti), and the like and may include a single layer or layers. In an embodiment, for example, the first gate electrode G1 may be a single Mo layer.

The second gate insulating layer 13 may be disposed to cover the first gate electrode G1. The second gate insulating layer 13 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be ZnO and/or ZnO₂. The second gate insulating layer 13 may include or be defined by a single layer or layers, each layer including at least one selected from the inorganic insulating materials described above.

A first upper electrode CE2 of the storage capacitor Cst may be disposed on the second gate insulating layer 13.

In the display area DA, the first upper electrode CE2 may overlap the first gate electrode G1 therebelow. The first gate electrode G1 and the first upper electrode CE2 overlapping each other with the second gate insulating layer 13 therebetween may constitute the storage capacitor Cst. The first gate electrode G1 may be a first lower electrode CE1 of the storage capacitor Cst.

The first upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may include or be defined by a single layer or layers, each layer including at least one selected from the materials described above.

The interlayer insulating layer 15 may be disposed to cover the first upper electrode CE2. The interlayer insulating layer 15 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be ZnO and/or ZnO₂. The interlayer insulating layer 15 may include or be defined by a single layer or layers, each layer including at least one selected from the inorganic insulating materials described above.

The first source electrode S1 and the first drain electrode D1 may be disposed on the interlayer insulating layer 15. The first source electrode S1 and the first drain electrode D1 may each include a conductive material including molybdenum (Mo), aluminum (Al), copper (Cu), titanium (Ti), and the like and may each include or be defined by a single layer or layers, each layer including at least one selected from the conductive materials described above. In an embodiment, for example, the first source electrode S1 and the first drain electrode D1 may each have a multilayer structure of Ti/Al/Ti.

The planarization layer 17 may be disposed to cover the first source electrode S1 and the first drain electrode D1. The planarization layer 17 may have a flat top surface so that the pixel electrode 21 disposed thereon is formed to be flat.

The planarization layer 17 may include an organic material or an inorganic material and may have a single-layer or multilayer structure. In an embodiment, the planarization layer 17 may include general-purpose polymer (e.g., benzocyclobutene (BCB), polyimide, HMDSO, polymethylmethacrylate (PMMA), or polystyrene (PS)), polymer derivatives having a phenolic group, acrylic polymer, imide-based polymer, aryl ether-based polymer, amide-based polymer, fluorine-based polymer, p-xylene-based polymer, or vinyl alcohol-based polymer. In an embodiment, the planarization layer 17 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). When the planarization layer 17 is formed, a layer may be formed, and then, chemical mechanical polishing may be performed on the top surface of the layer to provide a flat top surface.

The planarization layer 17 may have a via hole exposing one of the first source electrode S1 and the first drain electrode D1 of the thin-film transistor TFT, and the pixel electrode 21 may be in contact with the first source electrode S1 or the first drain electrode D1 through the via hole and may be electrically connected to the thin-film transistor TFT.

The pixel electrode 21 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). The pixel electrode 21 may include a reflection layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In an embodiment, for example, the pixel electrode 21 may have a structure including layers including ITO, IZO, ZnO, or In₂O₃ above/below the reflection layer. In such an embodiment, for example, the pixel electrode 21 may have a stack structure of ITO/Ag/ITO.

A pixel defining layer 19 may cover the edge of the pixel electrode 21 on the planarization layer 17 and may be provided with a first opening OP1 exposing the central portion of the pixel electrode 21. The size and shape of an emission area of the organic light-emitting diode OLED, that is, a sub-pixel, are defined by the first opening OP1.

The pixel defining layer 19 may effectively prevent an electric arc or the like from occurring on the edge of the pixel electrode 21 by increasing the distance between the edge of the pixel electrode 21 and an opposite electrode 23 on the pixel electrode 21. The pixel defining layer 19 may include an organic insulating material, such as polyimide, polyamide, acrylic resin, BCB, HMDSO, and phenol resin and may be formed by spin coating.

An emission layer 22b corresponding to the pixel electrode 21 may be arranged in the first opening OP1 of the pixel defining layer 19. The emission layer 22b may include a high molecular weight material or a low molecular weight material and may externally emit red light, green light, blue light, or white light.

An organic functional layer 22e may be disposed above and/or below the emission layer 22b. The organic functional layer 22e may include a first functional layer 22a and/or a second functional layer 22c. Alternatively, the first functional layer 22a or the second functional layer 22c may be omitted.

The first functional layer 22a may be disposed below the emission layer 22b. The first functional layer 22a may be defined by a single layer or layers, each layer including an organic material. The first functional layer 22a may be a hole transport layer (HTL) having a single-layer structure. Alternatively, the first functional layer 22a may include a hole injection layer (HIL) and an HTL. The first functional layer 22a may be integrally formed to correspond to the organic light-emitting diodes OLED included in the display area DA.

The second functional layer 22c may be disposed on the emission layer 22b. The second functional layer 22c may be a single layer or layers including an organic material. The second functional layer 22c may include an electron transport layer (ETL) and/or an electron injection layer (EIL). The second functional layer 22c may be integrally or commonly formed to correspond to the organic light-emitting diodes OLED included in the display area DA.

The opposite electrode 23 may be disposed on the second functional layer 22c. The opposite electrode 23 may include a conductive material having a low work function. In an embodiment, for example, the opposite electrode 23 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 23 may further include a layer including ITO, IZO, ZnO, or In₂O₃ on the (semi) transparent layer including the material described above. The opposite electrode 23 may be integrally or commonly formed to correspond to the organic light-emitting diodes OLED included in the display area DA.

The layers formed in the display area DA, from the pixel electrode 21 to the opposite electrode 23, may constitute the organic light-emitting diode OLED.

An upper layer 25 including an organic material may be disposed on the opposite electrode 23. The upper layer 25 may be a layer provided to protect the opposite electrode 23 and increase light extraction efficiency. The upper layer 25 may include an organic material having a refractive index higher than that of the opposite electrode 23. Alternatively, the upper layer 25 may be provided by stacking layers having different refractive indices. In an embodiment, for example, the upper layer 25 may be provided by stacking a high refractive index layer, a low refractive index layer, and a high refractive index layer. In such an embodiment, the refractive index of the high refractive index layer may be about 1.7 or greater and the refractive index of the low refractive index layer may be about 1.3 or less.

The upper layer 25 may further include LiF. Alternatively, the upper layer 25 may further include an inorganic insulating material, such as silicon oxide (SiO₂) or silicon nitride (SiNₓ). The upper layer 25 may be omitted if desired. However, for convenience of description, an embodiment where the upper layer 25 is disposed on the opposite electrode 23 will be mainly described in detail.

The encapsulation layer described with reference to FIG. 6A or 6B may be disposed on the upper layer 25. In addition, a touch sensor layer may be disposed on the encapsulation layer.

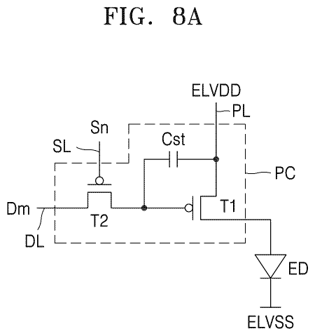

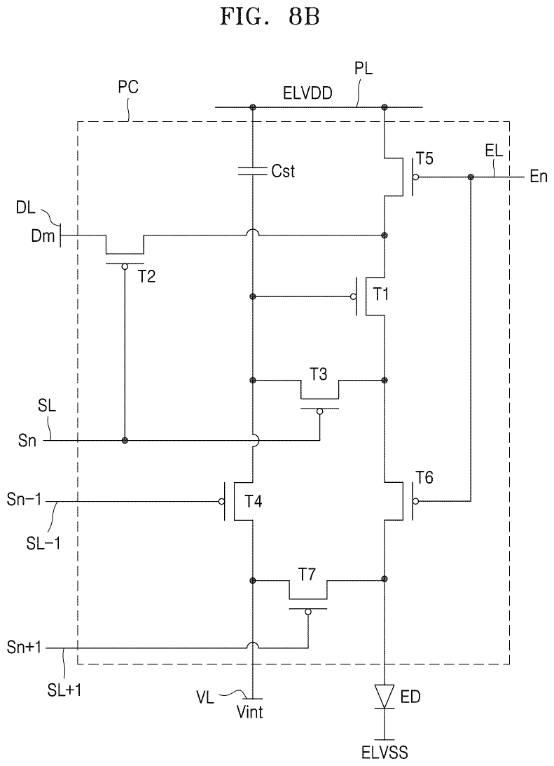

FIGS. 8A and 8B are schematic circuit diagrams of embodiments of a pixel of the display panel illustrated in FIG. 5.

Referring to FIGS. 8A and 8B, in an embodiment, a pixel circuit PC may be connected to a light-emitting element ED to implement light emission of sub-pixels. The pixel circuit PC may include a driving thin-film transistor T1, a switching thin-film transistor T2, and a storage capacitor Cst. The switching thin-film transistor T2 may be connected to a scan line SL and a data line DL and may be configured to transmit, to the driving thin-film transistor T1, a data signal Dm input through the data line DL in response to a scan signal Sn input through the scan line SL.

The storage capacitor Cst may be connected to the switching thin-film transistor T2 and a driving voltage line PL and may be configured to store a voltage corresponding to the difference between a voltage received from the switching thin-film transistor T2 and a driving voltage ELVDD supplied to the driving voltage line PL.

The driving thin-film transistor T1 may be connected to the driving voltage line PL and the storage capacitor Cst and may be configured to control a driving current flowing from the driving voltage line PL to the light-emitting element ED corresponding to a voltage value stored in the storage capacitor Cst. The light-emitting element ED may be configured to emit light having a certain luminance corresponding to the driving current.

Although FIG. 8A illustrates an embodiment where the pixel circuit PC includes two thin-film transistors and one storage capacitor, the disclosure is not limited thereto.

Referring to FIG. 8B, in another embodiment, a pixel circuit PC may include a driving thin-film transistor T1, a switching thin-film transistor T2, a compensation thin-film transistor T3, a first initialization thin-film transistor T4, an operation control thin-film transistor T5, an emission control thin-film transistor T6, and a second initialization thin-film transistor T7.

Although FIG. 8B illustrates an embodiment where signal lines SL, SL−1, SL+1, EL, and DL, an initialization voltage line VL, and a driving voltage line PL are provided for each pixel circuit PC, the disclosure is not limited thereto. In another embodiment, the initialization voltage line VL and/or at least one of the signal lines SL, SL−1, SL+1, EL, and DL may be shared by neighboring pixel circuits.

A drain electrode of the driving thin-film transistor T1 may be electrically connected to a light-emitting element ED via the emission control thin-film transistor T6. The driving thin-film transistor T1 may be configured (or connected) to receive a data signal Dm based on the switching operation of the switching thin-film transistor T2 and supply a driving current to the light-emitting element ED.

A gate electrode of the switching thin-film transistor T2 may be connected to the scan line SL and a source electrode of the switching thin-film transistor T2 may be connected to the data line DL. A drain electrode of the switching thin-film transistor T2 may be connected to a source electrode of the driving thin-film transistor T1 and connected to the driving voltage line PL via the operation control thin-film transistor T5.

The switching thin-film transistor T2 may be configured to be turned on in response to a scan signal Sn received through the scan line SL and perform a switching operation of transmitting the data signal Dm from the data line DL to the source electrode of the driving thin-film transistor T1.

A gate electrode of the compensation thin-film transistor T3 may be connected to the scan line SL. A source electrode of the compensation thin-film transistor T3 may be connected to the drain electrode of the driving thin-film transistor T1 and connected to a pixel electrode of the light-emitting element ED via the emission control thin-film transistor T6. A drain electrode of the compensation thin-film transistor T3 may be connected to one electrode of the storage capacitor Cst, a source electrode of the first initialization thin-film transistor T4, and a gate electrode of the driving thin-film transistor T1. The compensation thin-film transistor T3 may be configured to be turned on in response to the scan signal Sn received through the scan line SL and connect the gate electrode of the driving thin-film transistor T1 to the drain electrode of the driving thin-film transistor T1. Therefore, the driving thin-film transistor T1 may be diode-connected.

A gate electrode of the first initialization thin-film transistor T4 may be connected to the previous scan line SL−1. A drain electrode of the first initialization thin-film transistor T4 may be connected to the initialization voltage line VL. The source electrode of the first initialization thin-film transistor T4 may be connected to one electrode of the storage capacitor Cst, the drain electrode of the compensation thin-film transistor T3, and the gate electrode of the driving thin-film transistor T1. The first initialization thin-film transistor T4 may be configured to be turned on in response to a previous scan signal Sn−1 received through the previous scan line SL−1 and perform an initialization operation of transmitting an initialization voltage Vint to the gate electrode of the driving thin-film transistor T1 to initialize the voltage of the gate electrode of the driving thin-film transistor T1.

A gate electrode of the operation control thin-film transistor T5 may be connected to the emission control line EL. A source electrode of the operation control thin-film transistor T5 may be connected to the driving voltage line PL. A drain electrode of the operation control thin-film transistor T5 may be connected to the source electrode of the driving thin-film transistor T1 and the drain electrode of the switching thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and the source electrode of the compensation thin-film transistor T3. A drain electrode of the emission control thin-film transistor T6 may be electrically connected to the pixel electrode of the light-emitting element ED. The operation control thin-film transistor T5 and the emission control thin-film transistor T6 may be simultaneously turned on in response to an emission control signal En received through the emission control line EL and transmit a driving voltage ELVDD to the light-emitting element ED such that a driving current flows through the light-emitting element ED.

A gate electrode of the second initialization thin-film transistor T7 may be connected to the next scan line SL+1. A source electrode of the second initialization thin-film transistor T7 may be connected to the pixel electrode of the light-emitting element ED. A drain electrode of the second initialization thin-film transistor T7 may be connected to the initialization voltage line VL. The second initialization thin-film transistor T7 may be configured to be turned on in response to a next scan signal Sn+1 received through the next scan line SL+1 and initialize the pixel electrode of the light-emitting element ED.

Although FIG. 8B illustrates an embodiment where the first initialization thin-film transistor T4 and the second initialization thin-film transistor T7 are respectively connected to the previous scan line SL−1 and the next scan line SL+1, the disclosure is not limited thereto. In another embodiment, both the first initialization thin-film transistor T4 and the second initialization thin-film transistor T7 may be connected to the previous scan line SL−1 and may be driven in response to the previous scan signal Sn−1.

The other electrode of the storage capacitor Cst may be connected to the driving voltage line PL. One electrode of the storage capacitor Cst may be connected to the gate electrode of the driving thin-film transistor T1, the drain electrode of the compensation thin-film transistor T3, and the source electrode of the first initialization thin-film transistor T4.

An opposite electrode (e.g., a cathode) of the light-emitting element ED may be configured (or connected) to receive a common voltage ELVSS. The light-emitting element ED may be configured (or connected) to receive the driving current from the driving thin-film transistor T1 and externally emit light.

The pixel circuit PC is not limited to the number and circuit design of the thin-film transistors and the storage capacitor described with reference to FIGS. 8A and 8B, and the number and circuit design of the thin-film transistors and the storage capacitor may be variously modified.

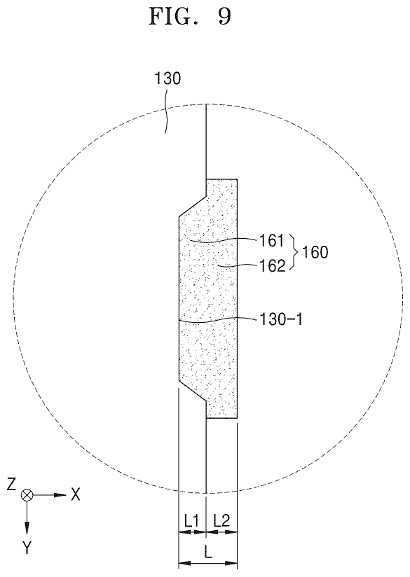

FIG. 9 is a rear view illustrating a portion of a display apparatus according to another embodiment.

Referring to FIG. 9, at least a portion of an accommodation groove 130-1 may have a trapezoidal shape. In a plan view or when viewed in the Z-axis direction, a portion of a reinforcement layer 160 may be arranged in the accommodation groove 130-1. In an embodiment, for example, the reinforcement layer 160 may include a first reinforcement layer 161 arranged inside the accommodation groove 130-1 and a second reinforcement layer 162 protruding outward from the accommodation groove 130-1. In such an embodiment, the first reinforcement layer 161 and the second reinforcement layer 162 may be connected to each other and may be integrally formed with each other as a single unitary indivisible part. In such an embodiment, a width L of the reinforcement layer 160 may be about 1 mm or less, as described above. That is, the sum of a first width L1 of the first reinforcement layer 161 and a second width L2 of the second reinforcement layer 162 may be about 1 mm or less.

The reinforcement layer 160 may be in contact with not only the edge of the accommodation groove 130-1 but also at least a portion of the edge of the display panel 130 around the accommodation groove 130-1 through the structure described above. By increasing the area in contact with the edge of the display panel 130, the reinforcement layer 160 may not be separated from the display panel 130, even when a force is applied to the display panel 130. In addition, the reinforcement layer 160 may reduce damage to the display panel 130 or separation between the display panel 130 and the cover member 110 due to the force applied to the edge of the display panel 130.

The form of the second reinforcement layer 162 is not limited thereto. That is, in an embodiment, the planar shape of the second reinforcement layer 162 may be rectangular as shown in FIG. 9, the second reinforcement layer 162 may be formed to have a round edge in another embodiment. In such an embodiment, the second width L2 may refer to the distance from the edge of the display panel 130 to a portion of the second reinforcement layer 162 that is farthest from the edge of the display panel 130 in the planar shape of the second reinforcement layer 162. In such an embodiment, the distance between the portion of the second reinforcement layer 162 and the edge of the display panel 130 may be measured in a direction perpendicular to the edge of the display panel 130.

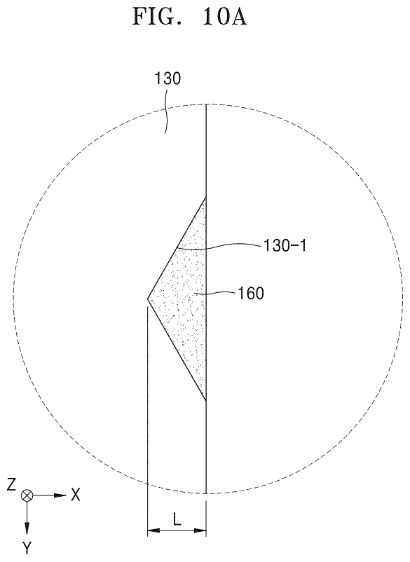

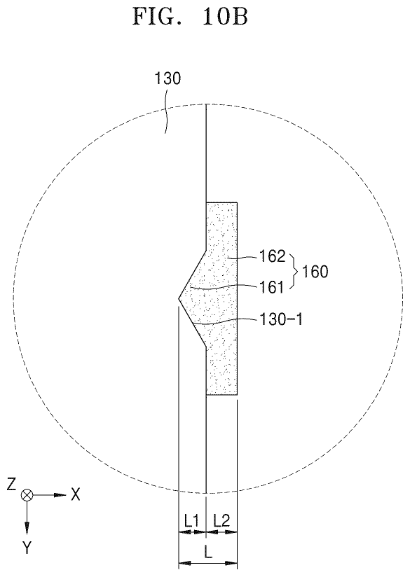

FIG. 10A is a rear view illustrating a portion of a display apparatus according to another embodiment.

Referring to FIG. 10A, in an embodiment, a planar shape of an accommodation groove 130-1 may be a polygonal shape, e.g., a triangular shape. Hereinafter, for convenience of description, an embodiment where the planar shape of the accommodation groove 130-1 is triangular will be described in detail.

In such an embodiment, a width of the planar shape of the accommodation groove 130-1 may be gradually reduced from one point to the end of the accommodation groove 130-1.

A reinforcement layer 160 may be inserted into the accommodation groove 130-1. In such an embodiment, the planar shape of the reinforcement layer 160 may correspond to the planar shape of the accommodation groove 130-1. In such an embodiment, the reinforcement layer 160 may be in contact with a display panel 130 at two or more portions of the edge of the display panel 130. The greatest width L of the reinforcement layer 160 may be about 1 mm or less. In such an embodiment, the edge of the reinforcement layer 160 may form an almost straight line with the edge of the display panel 130 in which the accommodation groove 130-1 is not formed.

FIG. 10B is a rear view illustrating a portion of a display apparatus according to another embodiment.

Referring to FIG. 10B, in an embodiment, a planar shape of an accommodation groove 130-1 may be triangular. In an embodiment, for example, a reinforcement layer 160 may include a first reinforcement layer 161 arranged inside the accommodation groove 130-1 and a second reinforcement layer 162 arranged outside the accommodation groove 130-1. In such an embodiment, the first reinforcement layer 161 and the second reinforcement layer 162 may be integrally formed as a single unitary indivisible body and may be in direct contact with the outer portion of the display panel 130. In addition, the planar shape of the first reinforcement layer 161 may correspond to the planar shape of the accommodation groove 130-1.

In such an embodiment, a width L of the reinforcement layer 160, which is the sum of a first width L1 of the first reinforcement layer 161 and a second width L2 of the second reinforcement layer 162, may be about 1 mm or less.

In addition, in an embodiment, the planar shape of the second reinforcement layer 162 may be rectangular as shown in FIG. 10 B, the second reinforcement layer 162 may be formed to have a round edge in another embodiment.

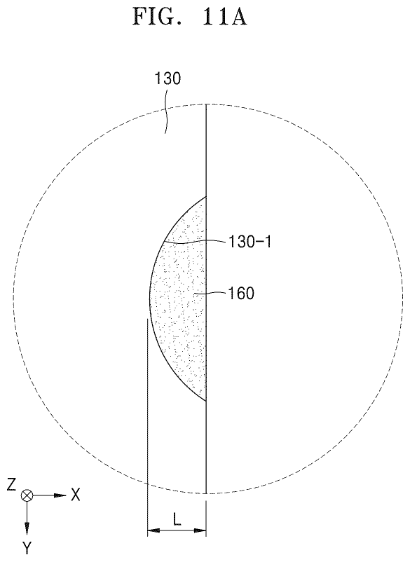

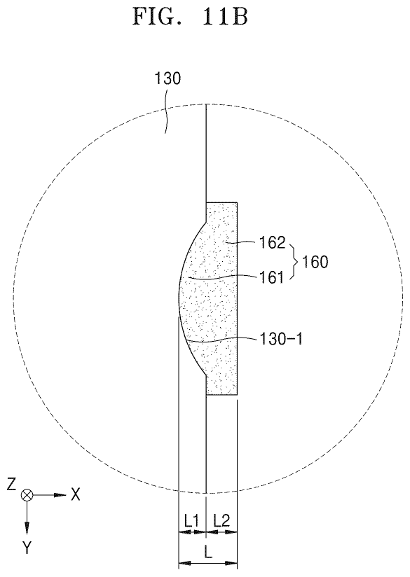

FIG. 11A is a rear view illustrating a portion of a display apparatus according to another embodiment.

Referring to FIG. 11A, in an embodiment, a planar shape of an accommodation groove 130-1 may be partially circular or elliptical. That is, the accommodation groove 130-1 may have a U-like shape. A width of the planar shape of the accommodation groove 130-1 may be gradually reduced from one point to the end of the accommodation groove 130-1.

A reinforcement layer 160 may be inserted into the accommodation groove 130-1. In such an embodiment, the planar shape of the reinforcement layer 160 may correspond to the planar shape of the accommodation groove 130-1. In such an embodiment, the greatest width L of the reinforcement layer 160 may be about 1 mm or less. In such an embodiment, the edge of the reinforcement layer 160 may form an almost straight line with the edge of the display panel 130 in which the accommodation groove 130-1 is not formed.

FIG. 11B is a rear view illustrating a portion of a display apparatus according to another embodiment.

Referring to FIG. 11B, in an embodiment, a planar shape of an accommodation groove 130-1 may be partially circular or elliptical. That is, a portion of the accommodation groove 130-1 may have a U-like shape, e.g., a shape of a semi-circle or a semi-ellipse. In an embodiment, for example, a reinforcement layer 160 may include a first reinforcement layer 161 arranged inside the accommodation groove 130-1 and a second reinforcement layer 162 arranged outside the accommodation groove 130-1. In such an embodiment, the first reinforcement layer 161 and the second reinforcement layer 162 may be integrally formed as a single unitary indivisible body and may be in direct contact with the outer portion of the display panel 130. In addition, the planar shape of the first reinforcement layer 161 may correspond to the planar shape of the accommodation groove 130-1.

In such an embodiment, a width L of the reinforcement layer 160, which is the sum of a first width L1 of the first reinforcement layer 161 and a second width L2 of the second reinforcement layer 162, may be about 1 mm or less.

In addition, in an embodiment, the planar shape of the second reinforcement layer 162 may be rectangular as shown in FIG. 11B, the second reinforcement layer 162 may be formed to have a round edge in another embodiment.

The display apparatus according to one or more embodiments may effectively prevent separation between the display panel and the cover member.

The display apparatus according to one or more embodiments may substantially or effectively reduce damage caused by an external force applied to the corners of the display apparatus.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a display panel provided with an accommodation groove defined in an outer portion thereof;
a cover member disposed on the display panel; and
a reinforcement layer accommodated in at least a portion of the accommodation groove and attached to the cover member.

2. The display apparatus of claim 1, wherein a planar shape of the accommodation groove is polygonal or a U-like shaped.

3. The display apparatus of claim 1, wherein a planar shape of the display panel is rectangular, and
the accommodation groove is defined on a short side of the planar shape of the display panel.

4. The display apparatus of claim 1, wherein the reinforcement layer comprises:
a first reinforcement layer disposed inside the accommodation groove; and
a second reinforcement layer disposed outside of the accommodation groove.

5. The display apparatus of claim 4, wherein a sum of a width of the first reinforcement layer and a width of the second reinforcement layer is about 1 mm or less.

6. The display apparatus of claim 1, further comprising a support on which the cover member is seated.

7. The display apparatus of claim 6, wherein an inner side surface of the support and the reinforcement layer are apart from each other.

8. The display apparatus of claim 1, wherein the display panel comprises an organic light-emitting element.

9. The display apparatus of claim 1, wherein a width of a planar shape of the accommodation groove is gradually reduced from one point to an end of a planar shape of the accommodation groove.

10. The display apparatus of claim 1, wherein the accommodation groove is provided in plurality, and
one of a plurality of accommodation grooves and another of the plurality of accommodation grooves are arranged to be symmetrical to each other with respect to an imaginary straight line perpendicular to one side of the display panel.

11. A display apparatus comprising:
a display panel;
a cover member disposed on the display panel;
a reinforcement layer inserted into the display panel; and
a support disposed apart from the reinforcement layer and supporting the cover member.

12. The display apparatus of claim 11, wherein a planar shape of the reinforcement layer is polygonal, partially circular, or partially elliptical.

13. The display apparatus of claim 11, wherein the reinforcement layer is in contact with the cover member.

14. The display apparatus of claim 11, wherein a portion of the reinforcement layer is inserted into the display panel, and another portion of the reinforcement layer protrudes outward from the display panel in a plan view.

15. The display apparatus of claim 11, wherein the display panel has a rectangular shape, and
the reinforcement layer is arranged on a short side of the display panel.

16. The display apparatus of claim 11, wherein the reinforcement layer is provided in plurality, and
one of a plurality of reinforcement layers and another reinforcement layer are arranged to be symmetrical to each other with respect to one side of the display panel.

17. The display apparatus of claim 11, wherein the reinforcement layer is in contact with an edge of the display panel on at least two sides.

18. The display apparatus of claim 11, wherein a width of the reinforcement layer is gradually reduced from one point to an end of the reinforcement layer.

19. The display apparatus of claim 11, wherein an edge of the reinforcement layer and an edge of the display panel form a straight line.

20. The display apparatus of claim 11, further comprising a bracket on which the support is seated.
